(19) United States
(12) Patent Application Publication
(10) Pub. No.: US 2025/0349738 A1
(43) Pub. Date: Nov. 13, 2025

(54) LAYOUT OF SCRIBE LINE FEATURES

(71) Applicant: Taiwan Semiconductor Manufacturing Company, Ltd., Hsinchu (TW)

(72) Inventors: Chang-Ching Yu, Hsinchu City (TW); Wei-Ti Hsu, Hsinchu County (TW)

(21) Appl. No.: 19/274,332

(22) Filed: Jul. 18, 2025

Related U.S. Application Data
(63) Continuation of application No. 18/323,688, filed on May 25, 2023.
(60) Provisional application No. 63/420,390, filed on Oct. 28, 2022.

(51) Int. Cl. H01L 23/544; H10D 64/01

(52) U.S. Cl. CPC H01L 23/544; H10D 64/017; H01L 2223/5446

(57) ABSTRACT

The present disclosure provides method to generate a dummy pad pattern. A method according to embodiment of the present disclosure includes receiving a design layout that includes a device region disposed in a scribe line region, identifying a center portion of the scribe line region surrounding the device region and an edge portion surrounding the center portion, dividing the edge portion into a plurality of rectangular areas, super-positioning a dummy pattern on each of the plurality of rectangular areas to obtain edge dummy patterns, super-positioning the dummy pattern on the center portion to obtain center dummy patterns, carving out a portion of the dummy pattern corresponding to the device region from the center dummy patterns to obtain net center dummy patterns, generating a scribe line dummy pattern based on the edge dummy patterns and the net center dummy patterns, and fabricating a first photomask including the scribe line dummy pattern.

### PRIORITY DATA

The present application is a continuation application of U.S. patent application Ser. No. 18/323,688, filed May 25, 2023, which claims the benefit of U.S. Provisional Application No. 63/420,390, filed Oct. 28, 2022, each of which is incorporated herein by reference in its entirety.

### BACKGROUND

As three-dimensional (3D) integrated circuit (IC) packing gains popularity in the semiconductor industry, efficient ways to perform wafer-to-wafer (WoW) bonding have been explored. A WoW bonding technology includes implementation of bonding layers on different IC dies. Each of the bonding layer includes metal features embedded in a dielectric layer. For the bonding layers to serve the WoW bonding, the metal features and surfaces of the dielectric layer of different bonding layers should be aligned. When the metal features of two bonding layers are not aligned, the bonding may become compromised.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a fragmentary cross-sectional view of a top die and a bottom die bonded together by way of bonding layers, according to one or more aspects of the present disclosure.

FIGS. 2-8 illustrate operations to design a wafer-level dummy pad pattern for scribe line regions, according to one or more aspects of the present disclosure.

FIG. 9 is a flow chart illustrating an example embodiment of a method of designing a wafer-level dummy pad pattern for scribe line regions, according to one or more aspects of the present disclosure.

FIGS. 10-28 illustrate operations of the method in FIG. 9 being performed to various design layouts, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Multi-dimensional integrated chips are generally formed by stacking multiple semiconductor substrates (e.g., semiconductor wafers) onto one another. For example, during a multi-dimensional integrated chip fabrication process, a top wafer may be flipped over and bonded to a bottom wafer to achieve wafer-to-wafer communication. The bonding of the top wafer and the bottom wafer may be achieved by way of a wafer glue layer. In some instances, the wafer glue layer includes a first bonding layer disposed on the top wafer and a second bonding layer disposed on the bottom wafer. Each of the first bonding layer and the second bonding layer includes metal features disposed in a dielectric layer. To achieve strong bonding, the metal features in the first bonding layer and the second bonding layer are vertically aligned and the exposed dielectric layers in the first bonding layer and the second bonding layer are vertically aligned as well. Besides device regions, the first bonding layer and the second bonding layer also cover scribe line regions. The metal features in the first bonding layer and the second bonding layer over the scribe line regions do not serve electrical functions and may be referred to as dummy features. The dummy features in the scribe line regions, however, serve wafer bonding functions. When dummy features in the first bonding layer and the second bonding layer are not vertically aligned, the wafer-to-wafer bonding may be weakened or compromised.

The present disclosure provides methods to generate dummy pad patterns in a photomask design. These methods include performance of multiple alignments or overlays of a dummy pattern with edge portions and a center portion of a device layout design. For example, when a first die is to be bonded to a second die, both the first die and the second die may be fabricated on the same wafer. When using stepwise photolithographic exposure to form dummy pad patterns of the first die and the second die, adjacent exposure areas may share a portion of the scribe line regions because the dummy pad patterns on scribe line regions are symmetric due to use of the method of the present disclosure.

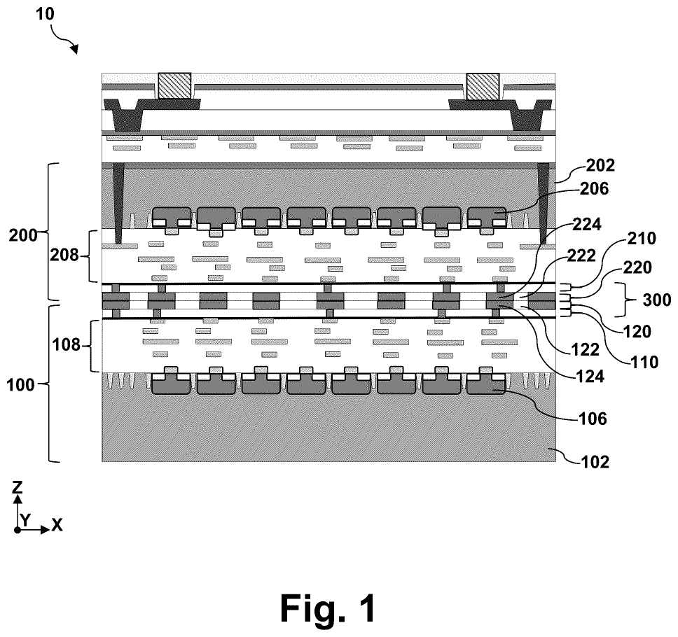

FIG. 1 illustrates a fragmentary cross-sectional view of a package structure 10. The package structure 10 includes a top die 200 flipped over and bonded to a bottom die 100 by way of a wafer glue layer 300. The bottom die 100 includes a first substrate 102, a plurality of first transistors 106 fabricated on the first substrate 102, and a first interconnect structure 108 over the first substrate 102. The top die 200 includes a second substrate 202, a plurality of a second transistors 206 fabricated on the second substrate 202, and a second interconnect structure 208 over the second substrate 202. In an embodiment, both the first substrate 102 and the second substrate 202 include silicon (Si). Alternatively, the first substrate 102 and the second substrate 202 may include a compound semiconductor, such as silicon carbide (SiC), gallium arsenide (GaAs), gallium phosphide (GaP), indium phosphide (InP), indium arsenide (InAs), and/or indium antimonide; an alloy semiconductor, such as silicon germanium (SiGe), GaAsP, AlInAs, AlGaAs, GaInAs, GaInP, and/or GaInAsP; or combinations thereof. Alternatively, the first substrate 102 and the second substrate 202 may be semiconductor-on-insulator substrates, such as a silicon-on-insulator (SOI) substrates, silicon germanium-on-insulator (SGOI) substrates, or germanium-on-insulator (GeOI) substrates. Semiconductor-on-insulator substrates can be fabricated using separation by implantation of oxygen (SIMOX), wafer bonding, and/or other suitable methods. Both the first substrate 102 and the second substrate 202 can include various doped regions depending on design requirements.

Referring still to FIG. 1, each of the first transistors 106 and the second transistors 206 may be a planar transistor or a multi-gate transistor, such as a fin-like field effect transistor (FinFET) or a gate-all-around (GAA) transistor. A planar transistor includes a gate structure that may induce a planar channel region along one surface of its active region, hence its name. A FinFET includes a fin-shaped active region arising from a substrate and a gate structure disposed over a top surface and sidewalls of the fin-shaped active region. A GAA transistor includes at least one channel member extending between two source/drain features and a gate structure that wraps completely around the at least one channel member. Because its gate structure wraps around the channel member, a GAA transistor may also be referred to as a surrounding gate transistor (SGT) or a multi-bridge-channel (MBC) transistor. Depending on the shapes and orientation, a channel member in a GAA transistor may be referred to as a nanosheet, a semiconductor wire, a nanowire, a nanostructure, a nano-post, a nano-beam, or a nano-bridge. In some instances, a GAA transistor may be referred to by the shape of the channel member. For example, a GAA transistor having one or more nanosheet channel member may also be referred to as a nanosheet transistor or a nanosheet FET.

Referring to FIG. 1, each of the first interconnect structure 108 and the second interconnect structure 208 may include three (3) to sixteen (16) metal layers to functional link the first transistors 106 or the second transistors 206. For case of illustration, each of the first interconnect structure 108 and the second interconnect structure 208 is shown to include 4 metal layers shown in FIG. 1 are representatively shown as dots. It should be understood that each of the first interconnect structure 108 and the second interconnect structure 208 may include less or more metal layers. In one embodiment, the first interconnect structure 108 includes six (6) metal layers and the second interconnect structure 208 includes seven (7) metal layers. Each of the metal layers includes an etch stop layer (ESL) and an intermetal dielectric (IMD) layer disposed on the ESL. With respect to each of the first interconnect structure 108 and the second interconnect structure 208, it can be said that ESLs interleave the IMD layers or that IMD layers interleave the ESLs. The ESLs may include silicon carbide, silicon nitride or silicon oxynitride. The IMD layers may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), low-k dielectric material, other suitable dielectric material, or combinations thereof. Example low-k dielectric materials include carbon doped silicon oxide, Xerogel, Aerogel, amorphous fluorinated carbon, benzocyclobutene (BCB), or polyimide.

Each of the metal layers of the first interconnect structure 108 and the second interconnect structure 208 includes a plurality of vertically extending vias and horizontally extending metal lines. The contact vias and metal lines in the first interconnect structure 108 and the second interconnect structure 208 may include copper (Cu), tantalum (Ta), nickel (Ni), cobalt (Co), aluminum (Al), or a combination thereof. In one embodiment, the contact vias, metal lines, and the top metals may include copper (Cu). While not explicitly shown, the contact vias, metal lines and top metal features may further include a barrier layer to interface the oxygen-containing IMDs. The barrier layer may include titanium nitride (TiN), tantalum nitride (TaN), manganese nitride (MnN), or other transition metal nitride.

The bottom die 100 includes a back side adjacent the first substrate 102 and a front side adjacent the first interconnect structure 108. The top die 200 includes a back side adjacent the second substrate 202 and a front side adjacent the second interconnect structure 208. On its front side, the bottom die 100 includes a first pad contact layer 110 and a first pad layer 120 over the first pad contact layer 110. The top die 200 includes a second pad contact layer 210 and a second pad layer 220 over the second pad contact layer 210. The first pad layer 120 includes first metal pads 124 embedded in a first dielectric layer 122. The second pad layer 220 includes second metal pads 224 embedded in a second dielectric layer 222. As shown in FIG. 1, the first pad contact layer 110 function to electrically couple the first interconnect structure 108 to the first metal pads 124 in the first pad layer 120. The second pad contact layer 210 function to electrically couple the second interconnect structure 208 to the second metal pads 224 in the second pad layer 220. When the top die 200 is bonded to the bottom die 100, the first metal pads 124 and the second metal pads 224 are vertically aligned and the exposed surfaces of the first dielectric layer 122 and the second dielectric layer 222 are also aligned to maximize metal-to-metal as well as dielectric-to-dielectric contact. The first dielectric layer 122 and the second dielectric layer 222 may have a composition similar to the IMD layers described above. The first metal pads 124 and the second metal pads 224 may include copper (Cu), tantalum (Ta), nickel (Ni), cobalt (Co), aluminum (Al), a combination thereof, or an alloy thereof. In one embodiment, the first metal pads 124 and the second metal pads 224 may include copper (Cu). The first pad contact layer 110, the first pad layer 120, the second pad contact layer 210, and the second pad layer 220 may be collectively referred to as the wafer glue layer 300.

In an example process to bond the top die 200 to the bottom die 100, the first pad layer 120 and the second pad layer 220 are planarized by, for example, a CMP process. Then, surfaces of the first pad layer 120 and the second pad layer 220 are cleaned to remove organic and metallic contaminants. For example, a sulfuric acid hydrogen peroxide mixture (SPM), a mixture of ammonium hydroxide and hydrogen peroxide (SC1), or both may be used to remove organic contaminants on surfaces of the first metal pads 124, the first dielectric layer 122, the second metal pads 224, and the second dielectric layer 222. A mixture of hydrochloric acid and hydrogen peroxide (SC2) may be used to remove metallic contaminants. Besides cleaning, the first metal pads 124, the first dielectric layer 122, the second metal pads 224, and the second dielectric layer 222 may be treated by an argon plasma or a nitrogen plasma to activate the surfaces thereof. After the first metal pads 124 are aligned with the second metal pads 224, an anneal is performed to promote the van der Waals force bonding of the first dielectric layer 122 and the second dielectric layer 222 as well as the surface-activated bonding (SAB) of the first metal pads 124 and the second metal pads 224. In some instances, the anneal includes a temperature between about 200° C. and about 300° C. It is noted that the first dielectric layer 122 and the second dielectric layer 222 are polished faster than first metal pads 124 and the second metal pad 224. In some instances, after the bottom die 100 is bonded to the top die 200, a gap between about 5 nm and about 50 nm may remain between surfaces of the first dielectric layer 122 and the second dielectric layer 222.

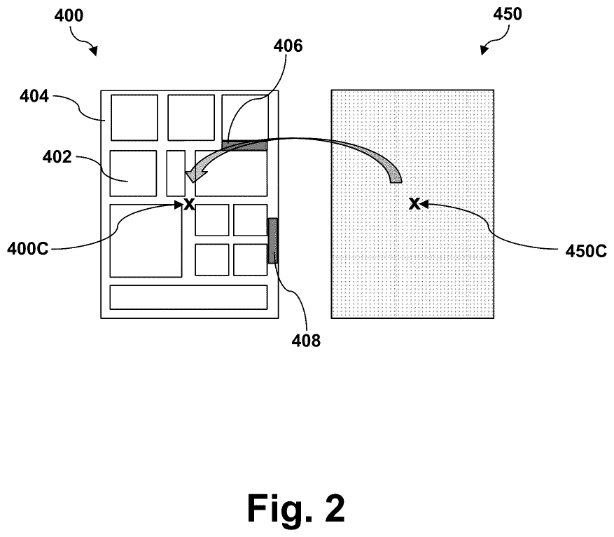

A die, such as the bottom die 100 and the top die 200 shown in FIG. 2, may include a device region and a scribe line region. The scribe line region is where the wafer is diced during a singulation process to obtain dies. Due to the nature of the scribe line region, devices or features that serve electrical functions after singulation are not fabricated in the scribe line region by design. That said, the scribe line region may include features that serve overlay, identification, process control, acceptance test, feature density control, or other functions before the singulation process. For example, the scribe line region may be home of overlay (OVL) patterns, critical dimension bar (CDBAR) patterns, process control monitor (PCM) patterns, identification (IDNT) patterns, wafer acceptance test (WAT) patterns, or dummy frame cells. When it comes to metal features in the wafer glue layer, such as the first metal pads 124 in the first pad layer 120 and the second metal pads 224 in the second pad layer 220, the metal features are formed not only over the device regions but also the scribe line regions. The metal features are placed in the scribe line regions for at least two reasons. First, the metal features in the scribe line regions can increase the pattern density in the otherwise isolated scribe line regions. Without these metal features, the scribe line regions may have smaller pattern density and damages may be resulted during a planarization process, such as a chemical mechanical polishing (CMP) process. Second, the metal features in the scribe line region may provide additional bonding surfaces, including metal surfaces and dielectric surfaces. Because the metal features of the first pad layer 120 and the second pad layer 220 in the scribe line regions do not serve any electrical functions and may be electrically floating, they may also be referred to as dummy pads, dummy features, or dummy pad features. In some instances, each of the dummy pads has a width or a diameter between about 0.2 μm and about 2.5 μm.

FIGS. 2-8 illustrate an example method to generate the dummy pad patterns for the scribe line regions of a design layout 400. Reference is first made to FIG. 2, which illustrates the design layout 400. The design layout includes at least one device region 402 surrounded by a scribe line region 404. It can be seen that the scribe line region 404 in FIG. 2 cuts between adjacent device regions 402. In some implementations illustrated in FIG. 2, the design layout 400 also includes an PCM pattern 406 and an OVL pattern 408 that fall within the scribe line region 404. In other embodiments not explicitly illustrated in FIG. 2, the PCM pattern 406 may be replaced with or include an OVL pattern, a CDBAR pattern, a IDNT pattern, or a WAT pattern. Likewise, the OVL pattern 408 may be replaced with or include a PCM pattern, a CDBAR pattern, a IDNT pattern, or a WAT pattern.

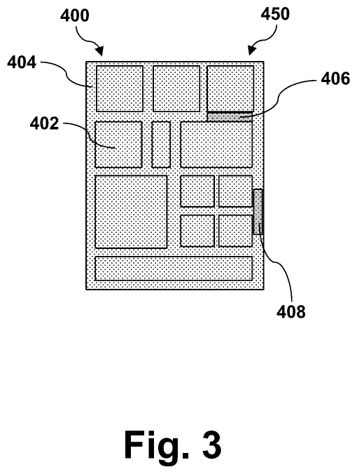

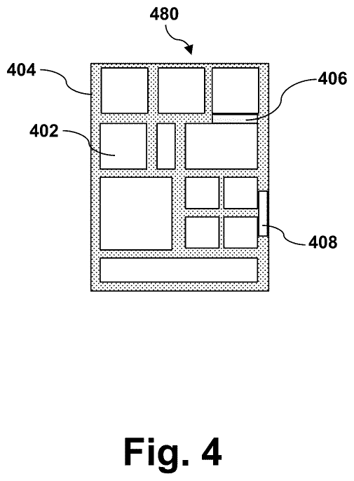

Referring still to FIG. 2, a dummy pattern 450 that includes dummy pad shapes is aligned with an entirety of the design layout 400 such as a geometric center 450C of the dummy pattern 450 vertical overlaps with a geometric center 400C of the design layout 400. As shown in FIG. 3, the dummy pattern 450 is super-positioned onto the design layout 400, including over the device regions 402, the scribe line region 404, the PCM pattern 406, and the OVL pattern 408. Referring to FIG. 4, after the alignment of the dummy pattern 450 with the design pattern 400, portions of the dummy pattern 450 directly over the device regions 402, the PCM pattern 406, and the OVL pattern 408 are removed or carved out. This operation is needed because the dummy pattern 450 will be fabricated on a photomask and the photomask is to be used in a photolithography process to form dummy pads in the scribe line region 404. Functional metal features will be formed over the device regions 402. Additionally, because dummy pads over the PCM pattern 406 and the OVL pattern 408 may hinder detection of the PCM pattern 406 and the OVL pattern 408, dummy pattern 450 over the PCM pattern 406 and the OVL pattern 408 should be removed. After the selective removal of the dummy pattern 450 from over device regions 402, the PCM pattern 406 and the OVL pattern 408, a dummy pad pattern 480 is generated, as shown in FIG. 4.

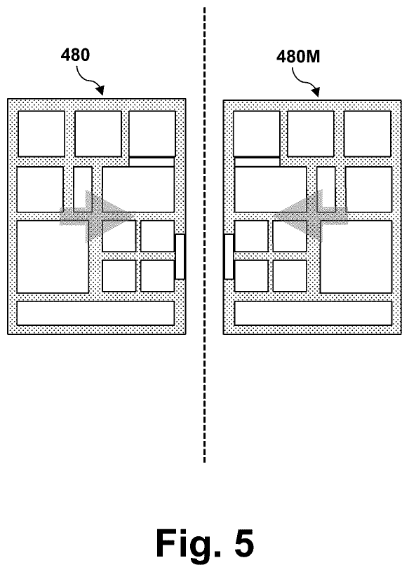

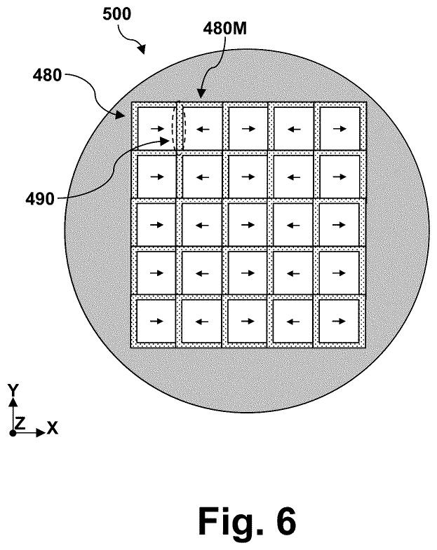

When patterning a wafer, a first photomask that includes the dummy pad pattern 480 and a second photomask that includes a mirror image 480M of the dummy pad pattern 480 may be fabricated. Images of the first photomask and the second photomask may be stepwise transferred on the wafer. The use of the first photomask and the second photomask ensures alignment of the bonding layers during the wafer-on-wafer (WoW) bonding process. Referring to FIG. 5, the arrow signs are applied to illustrate that the dummy pad pattern 480 and the mirror image 480M are mirror images of one another with respect to the dotted line. An exposure a semiconductor wafer 500 includes alternatingly stepping the dummy pad pattern 480 (on the first photomask) and the mirror image thereof (on the second photomask) across the semiconductor wafer 500 shown in FIG. 6 along the X direction as well as along the Y direction. For illustration purposes, each of the dummy pad patterns 480 in FIG. 6 is labeled with a right arrow (→) and each of the mirror images 480M in FIG. 6 is labeled with a left arrow (←). As shown in FIG. 6, images of the dummy pad pattern 480 are interleaved by images of the mirror image 480M along the X direction and the Y direction. It is noted that the semiconductor wafer 500 extend along the X-Y plane. To maximize throughput, neighboring images of a dummy pad pattern 480 and a mirror image 480M may share a double exposure portion 490 in the scribe line region. Because each of the design layout 400 is rectangular in shape, the double exposure portion 490 is an edge portion of the scribe line region and may be rectangular in shape. Because the alignment of the dummy pattern 450 with the design layout 400 is performed with respect to the geometric centers of the dummy pattern 450 and the design layout 400, the double exposure portion 490 may not be perfectly aligned.

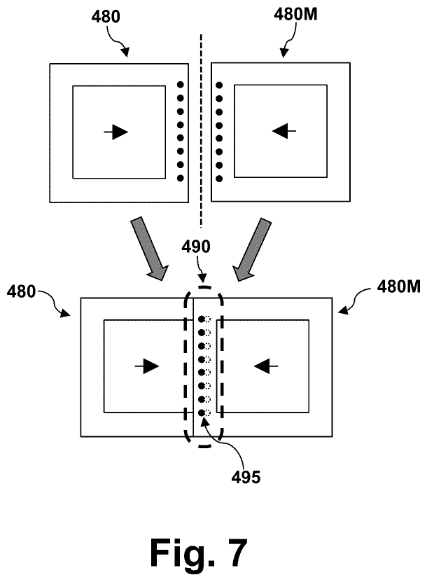

FIG. 7 illustrates a situation where the double exposure portion 490 is not perfectly aligned. In FIG. 7, the dummy pad pattern 480 includes an array of dummy pad shapes disposed closer to a right edge of the dummy pad pattern 480. As a mirror image of the dummy pad pattern 480, the mirror image 480M includes an array of dummy pad shapes disposed closer to a left edge of the mirror image 480M. When the scribe line region of the dummy pad pattern 480 is overlayed with the scribe line region of the mirror image 480M at the double exposure portion 490, the dummy pad shapes are not fully aligned and abnormal exposure images 495 may be resulted. It has been observed that such abnormal exposure images 495 may hinder vertical alignment of metal features, thereby weakening the wafer bonding. In some embodiments represented in the figures, each of the dummy pad shapes is circular. In some other embodiments, the dummy pad shapes may be rectangular or include a combination of circular and rectangular shapes.

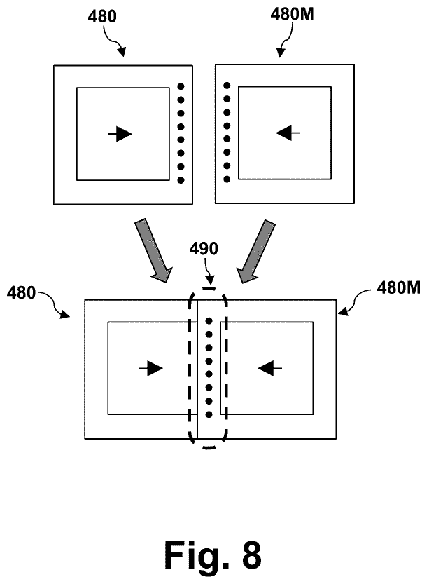

FIG. 8 illustrates a situation where the double exposure portion 490 happens to be perfectly aligned. In FIG. 8, the dummy pad pattern 480 includes an array of dummy pad shapes aligned with a geometric center of the scribe line region adjacent the right edge. As a mirror image of the dummy pad pattern 480, the mirror image 480M includes an array of dummy pad shapes aligned with a geometric center of the scribe line region adjacent the left edge. When the scribe line region of the dummy pad pattern 480 is overlayed with the scribe line region of the mirror image 480M at the double exposure portion 490, the dummy pad shapes are completely aligned. It has been observed that such completely alignment promotes vertical alignment of metal features, thereby strengthening the wafer bonding. It is noted that while the situation illustrated in FIG. 8 may happen if the dummy pattern 450 is aligned once with the design layout 400 with respect to their geometric center, there is no guarantee that it will always happen. As a result, it may result in process instability.

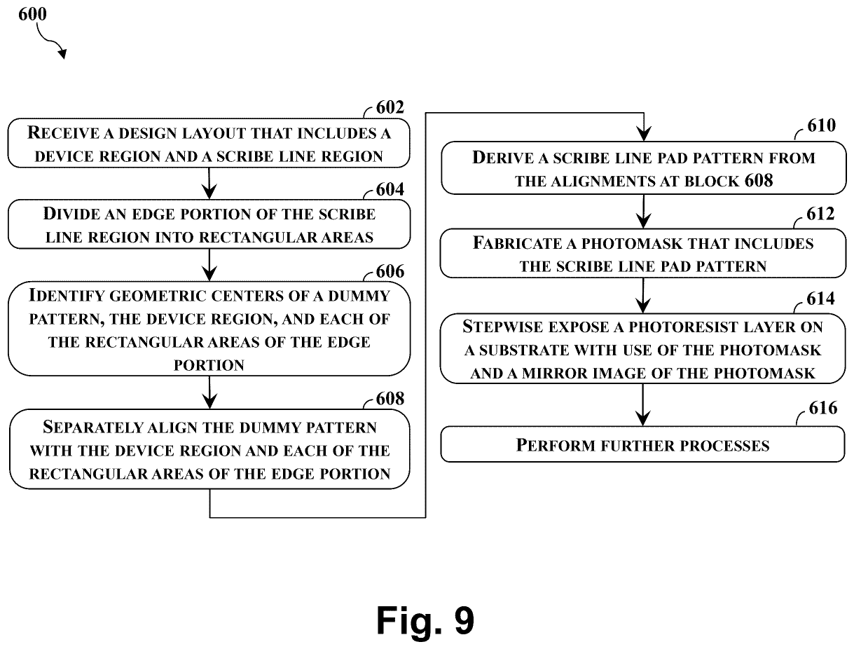

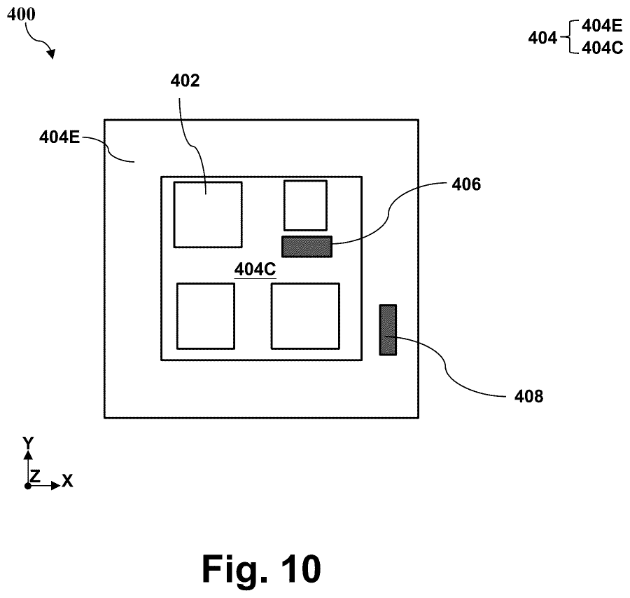

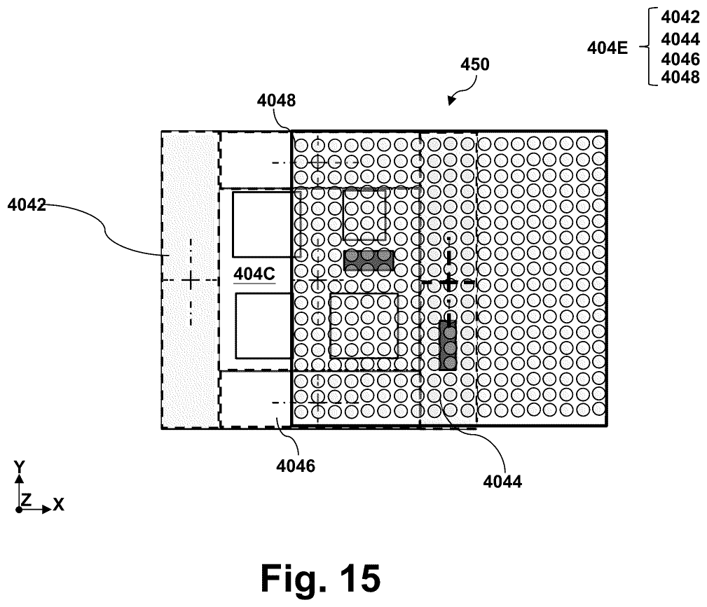

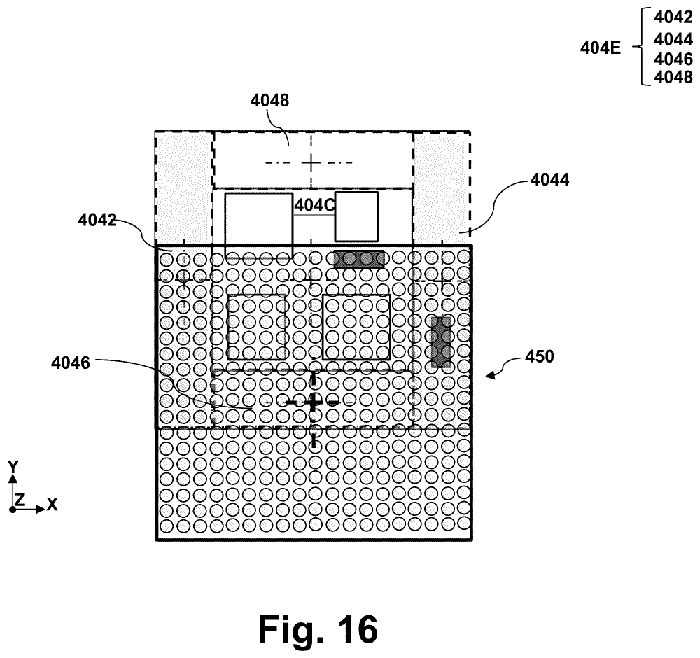

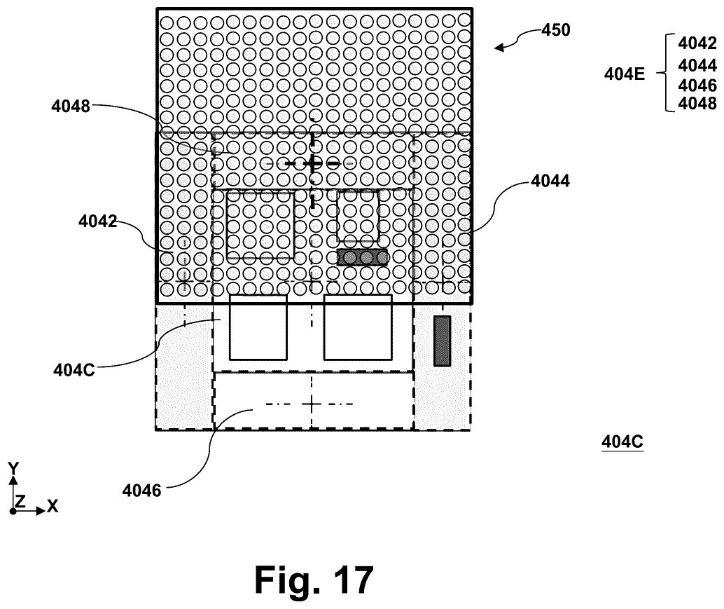

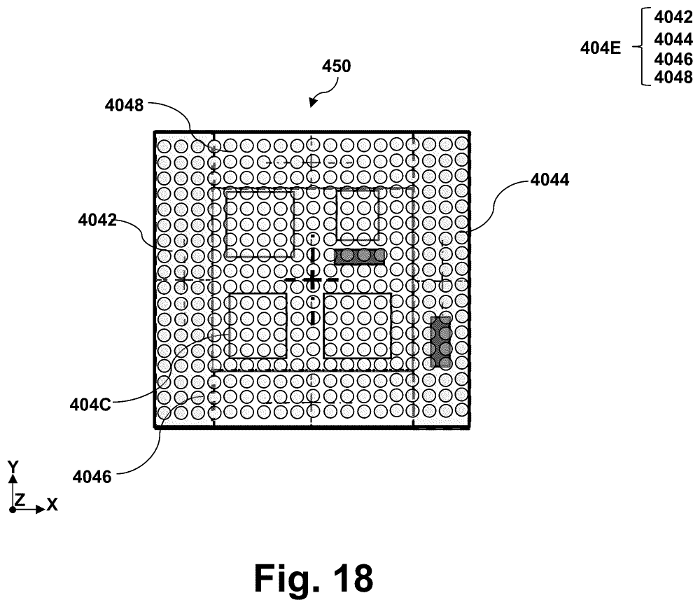

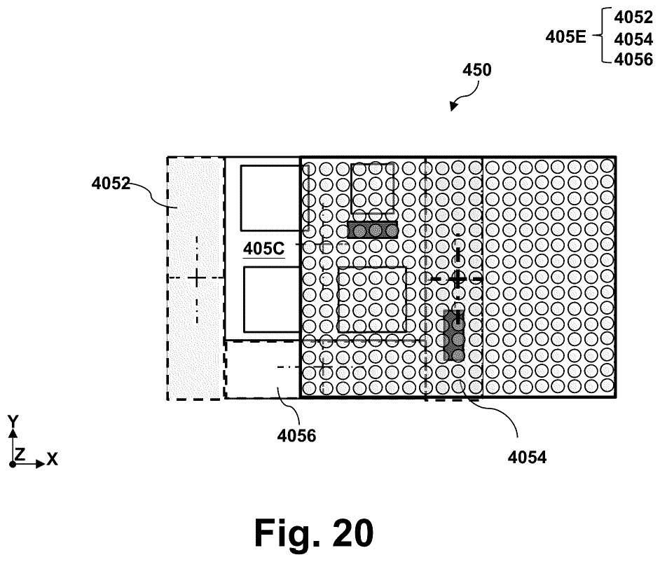

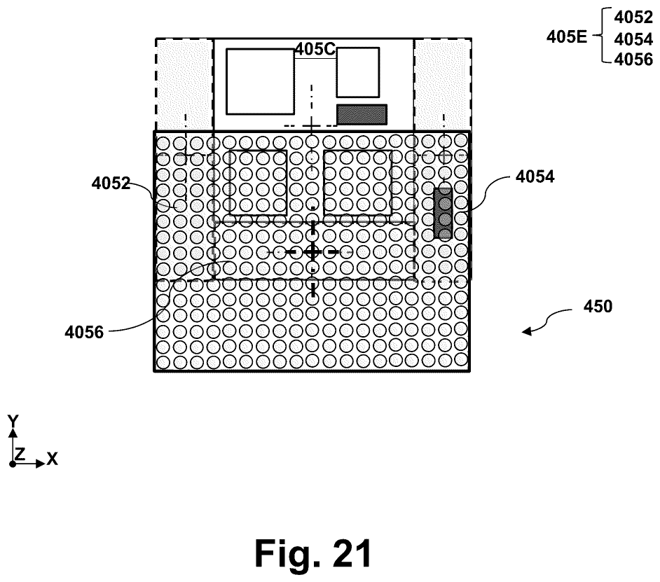

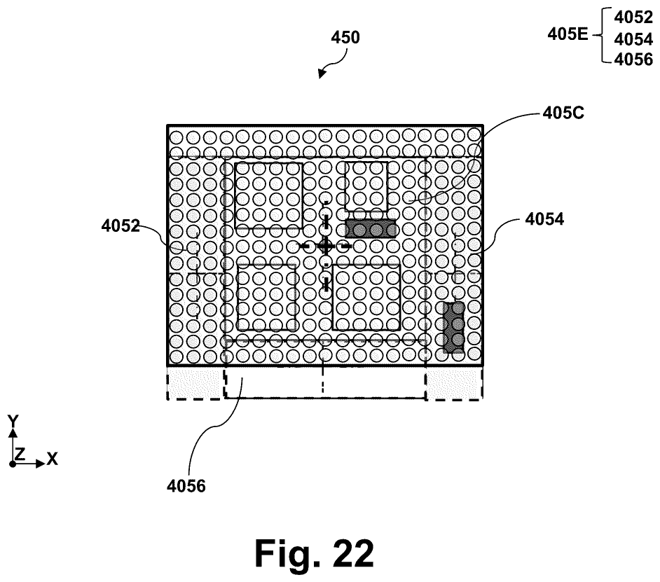

FIG. 9 is a flowchart illustrating a method 600 of fabricating a photomask. Method 600 is merely an example and is not intended to limit the present disclosure to what is explicitly illustrated in method 600. Additional steps can be provided before, during and after method 600, and some steps described can be replaced, eliminated, or moved around for additional embodiments of the method. Not all steps are described herein in detail for reasons of simplicity. Method 600 is described below in conjunction with FIG. 10-28, which include schematic top views of various design layouts, various dummy patterns, various photomask design, various photomasks, and a stepwise exposure of various photomasks. For avoidance of doubts, the X, Y and Z directions in FIGS. 10-28 are used consistently and perpendicular to one another. Throughout the present disclosure, unless expressly otherwise described, like reference numerals denote like features.

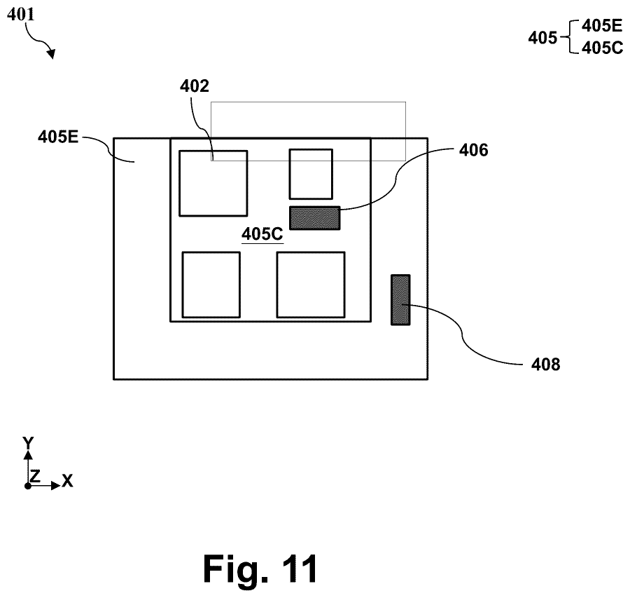

Referring to FIGS. 9-11, method 600 includes a block 602 where design layout is received. The design layer received at block 602 may be an O-frame design layout 400 or a U-frame design layout 401. The design layout 400 in FIG. 10 device regions 402 and a scribe line region 404. The scribe line region 404 includes an edge portion 404E and a center portion 404C. In some implementations illustrated in FIG. 10, the design layout 400 also includes an PCM pattern 406 and an OVL pattern 408 that fall within the scribe line region 404 (or the edge portion 404E). In other embodiments the PCM pattern 406 may be replaced with or include an OVL pattern, a CDBAR pattern, a IDNT pattern, or a WAT pattern. Likewise, the OVL pattern 408 may be replaced with or include a PCM pattern, a CDBAR pattern, a IDNT pattern, or a WAT pattern. The O-frame design layout 400 obtains it name because its edge portion 404E of the scribe line region 404 extends completely around the O-frame design layout 400. In some embodiments represented in FIG. 10, the O-frame design layout 400 are rectangular in shape on the X-Y plane. The U-frame design layout 401 in FIG. 11 includes device regions 402 and a scribe line region 405. The scribe line region 405 in FIG. 11 includes an edge portion 405E and a center portion 405C, wherein the edge portion 405E engages the center portion 405C on three sides. In some implementations illustrated in FIG. 11, the design layout 400 also includes an PCM pattern 406 and an OVL pattern 408 that fall within the scribe line region 405 (or the edge portion 405E). The PCM pattern 406 may be replaced with or include an OVL pattern, a CDBAR pattern, a IDNT pattern, or a WAT pattern. Likewise, the OVL pattern 408 may be replaced with or include a PCM pattern, a CDBAR pattern, a IDNT pattern, or a WAT pattern. The U-frame design layout 401 obtains it name because the edge portion 405E forms a U-shape. In some embodiments represented in FIG. 11, the U-frame design layout 401 are rectangular in shape on the X-Y plane. The device regions 402 are enclosed in the center portion 404C in FIG. 10 for the O-frame design layout 400 and in the center portion 405C in FIG. 11 for the U-frame design layout 401. For case of stepwise exposure operations, opposing edges of the edge portion 404E or the edge portion 405E have the same width to ensure completely vertical alignment.

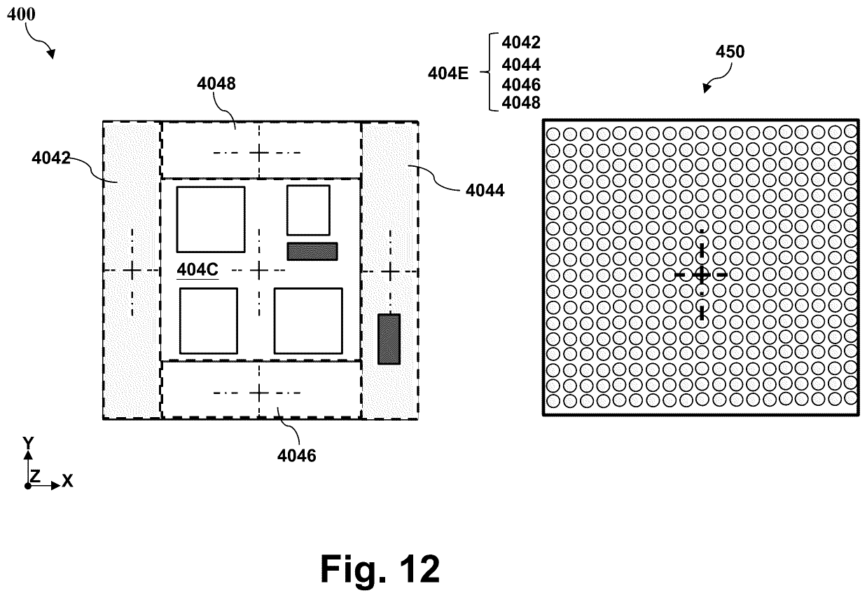

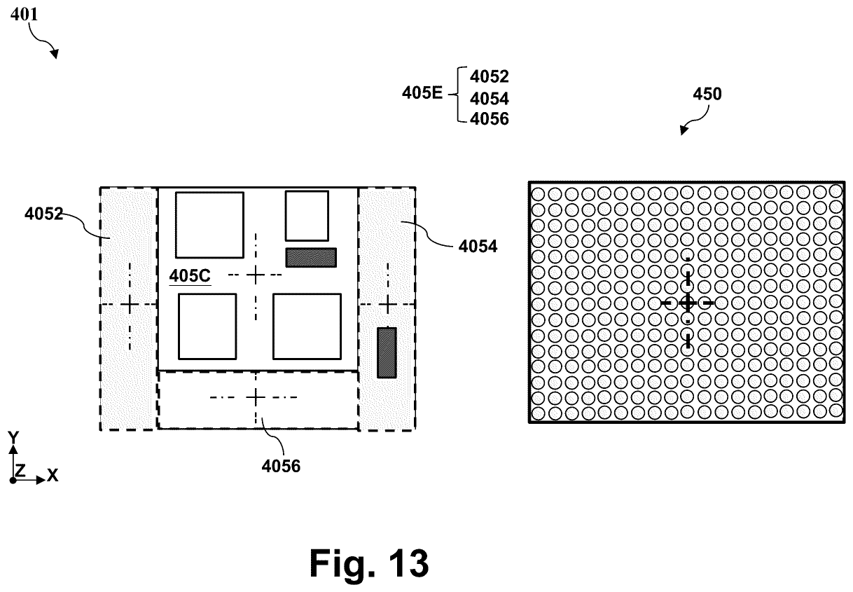

Referring to FIGS. 9 and 12-13, method 600 includes a block 604 where the edge portion of the scribe line region of the design layout is divided into rectangular areas. As shown in FIG. 12, the edge portion 404E of the O-frame design layout 400 may be divided into a first area 4042, a second area 4044, a third area 4046, and a fourth area 4048. Each of the first area 4042, the second area 4044, the third area 4046, and the fourth area 4048 is rectangular in shape. It is noted that the first area 4042 and the second area 4044 extend lengthwise along the Y direction and the third area 4046 and the fourth area 4048 extend lengthwise along the X direction. As shown in FIG. 13, the edge portion 405E of the U-frame design layout 401 may be divided into a first area 4052, a second area 4054, and a third area 4056. Each of the first area 4052, the second area 4054, and the third area 4056 is rectangular in shape. It is noted that the first area 4052 and the second area 4054 extend lengthwise along the Y direction and the third area 4056 extends lengthwise along the X direction. It should be understood that the edge portion 404E of the O-frame design layout 400 and the edge portion 405E of the U-frame design layout 401 may be divided differently for method 600 to work. For example, with respect to the O-frame design layout 400, the third area 4046 and the fourth area 4048 may extend all the way to the boundaries of the O-frame design layout 400 along the X direction and the first area 4042 and the second area 4044 only extend between the third area 4046 and the fourth area 4048 along the Y direction. For another example, with respect to the U-frame design layout 401, the third area 4056 may extend all the way to the boundaries of the U-frame design layout 401 along the X direction and the first area 4052 and the second area 4054 only extend from the third area 4056 along the Y direction.

Referring to FIGS. 9 and 12-13, method 600 includes a block 606 where geometric centers of a dummy pattern 450, the center portion region, and each of the rectangular areas are identified. As shown in FIG. 12, at block 606, the geometric centers or centroids (shown as a cross with dotted lines) are identified for the dummy pattern 450 as well as the center portion 404C, the first area 4042, the second area 4044, the third area 4046, and the fourth area 4048 of the O-frame design layout 400. As shown in FIG. 13, at block 606, the geometric centers or centroids (shown as a cross with dotted lines) are identified for the dummy pattern 450 as well as the center portion 405C, the first area 4052, the second area 4054 and the third area 4056 of the U-frame design layout 401. For avoidance of doubts, because the patterns, regions, and areas in FIG. 12 or 13 are rectangular in shape, the geometric centers of them are equidistant from boundaries along the X direction or the Y direction.

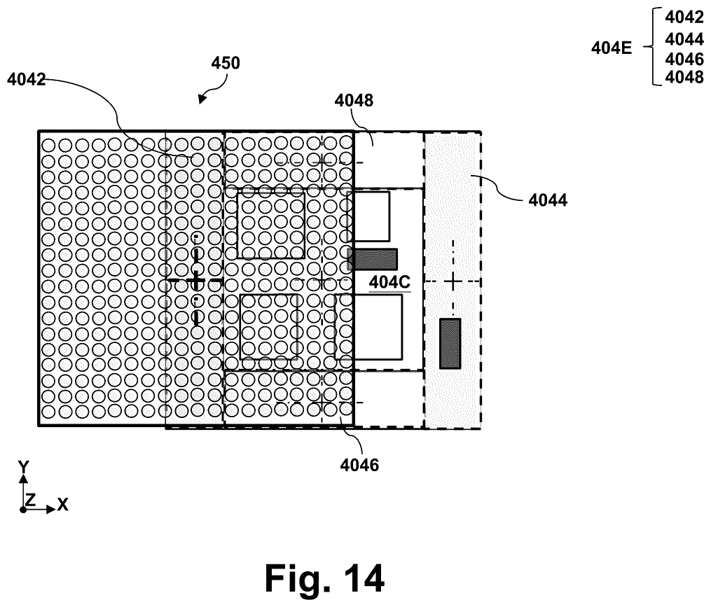

Referring to FIGS. 9 and 14-22, method 600 includes a block 608 where the dummy pattern 450 is separately aligned with the center portion and each of the rectangular areas of the edge portion of the scribe line region. As shown in FIGS. 14-18, with respect to the O-frame design layout 400, the dummy pattern 450 is overlayed to the first area 4042 such that their geometric centers completely overlaps; the dummy pattern 450 is overlayed to the second area 4044 such that their geometric centers completely overlaps; the dummy pattern 450 is overlayed to the third area 4046 such that their geometric centers completely overlaps; the dummy pattern 450 is overlayed to the fourth area 4048 such that their geometric centers completely overlaps; and the dummy pattern 450 is overlayed to the center portion 404C such that their geometric centers completely overlaps. Each of the alignment operations aims to obtain a portion of the dummy pattern 450 that overlaps with boundaries of each of the center portion 404C, the first area 4042, the second area 4044, the third area 4046, and the fourth area 4048. It is noted that the alignment operations for the O-frame design layout 400 may take place in any order.

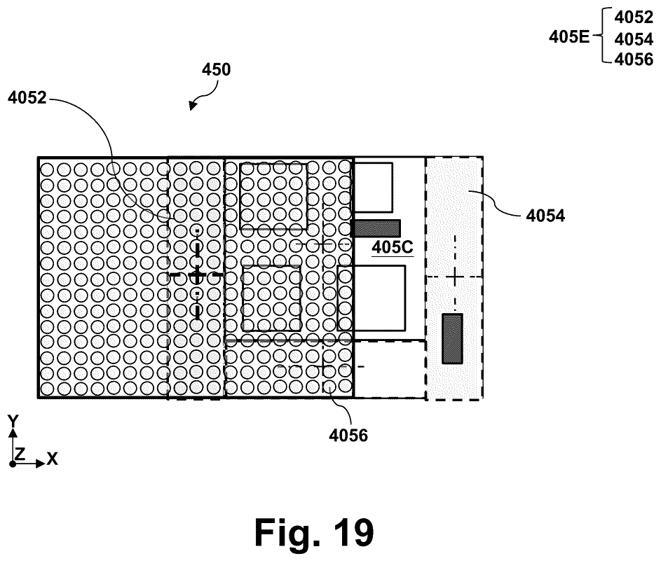

As shown in FIGS. 19-22, with respect to the U-frame design layout 401, the dummy pattern 450 is overlayed to the first area 4052 such that their geometric centers completely overlaps; the dummy pattern 450 is overlayed to the second area 4054 such that their geometric centers completely overlaps; the dummy pattern 450 is overlayed to the third area 4056 such that their geometric centers completely overlaps; and the dummy pattern 450 is overlayed to the center portion 405C such that their geometric centers completely overlaps. Each of the alignment operations aims to obtain a portion of the dummy pattern 450 that overlaps with boundaries of each of the center portion 405C, the first area 4052, the second area 4054, and the third area 4056. It is noted that the alignment operations for the U-frame design layout 401 may take place in any order. As describe above and illustrated in FIGS. 14-22, all alignment operations at block 608 are performed such that the geometric centers are aligned.

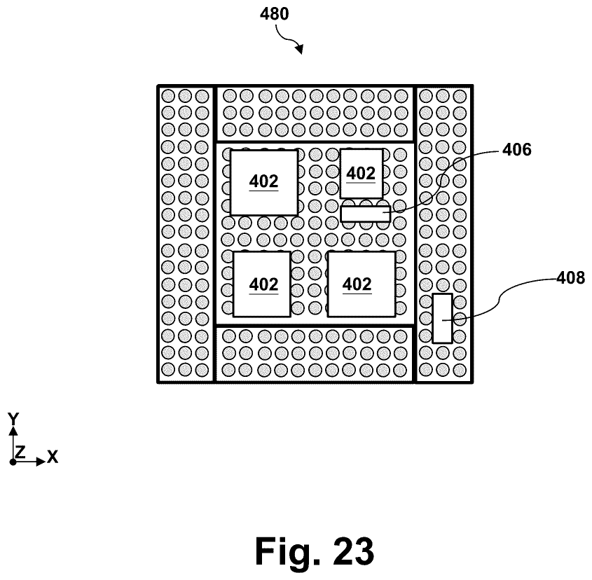

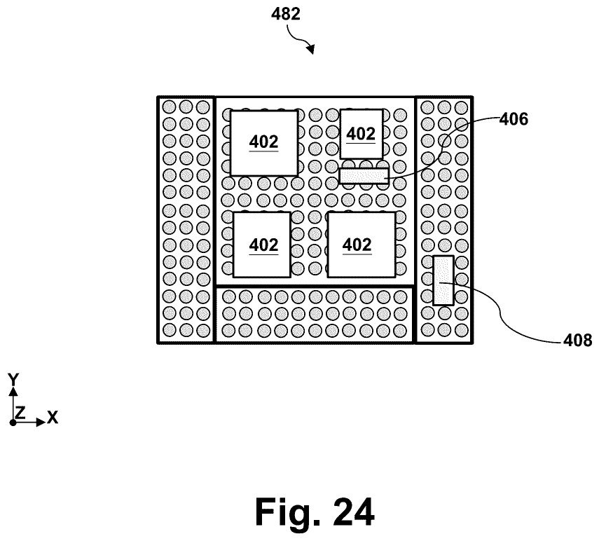

Referring to FIGS. 9 and 23-24, method 600 includes a block 610 where a scribe line pad pattern is derived from the alignments performed at block 608. Reference is first made to FIG. 23. In an example operation, images of the dummy patterns 450 aligned with the first area 4042, the second area 4044, the third area 4046, the fourth area 4048, and the center portion 404C of the O-frame design layout 400 are first combined to form a combined pattern and then images of the dummy patterns 450 over the device regions 402, the PCM pattern 406 and the OVL pattern 408 are selectively removed or carved out from the combined pattern to form a first scribe line pad pattern 480 (first net dummy pad pattern 480 or first dummy pad pattern 480). Reference is then made to FIG. 24. In an example operation, images of the dummy patterns 450 aligned with the first area 4052, the second area 4054, the third area 4056, and the center portion 405C of the U-frame design layout 401 are first combined to form a combined pattern and then image of the dummy pattern 450 over the device regions 402, the PCM pattern 406, and the OVL pattern 408 is removed or carved out from the combined pattern to form a second scribe line pad pattern 482 (second net dummy pad pattern 482 or second dummy pad pattern 482).

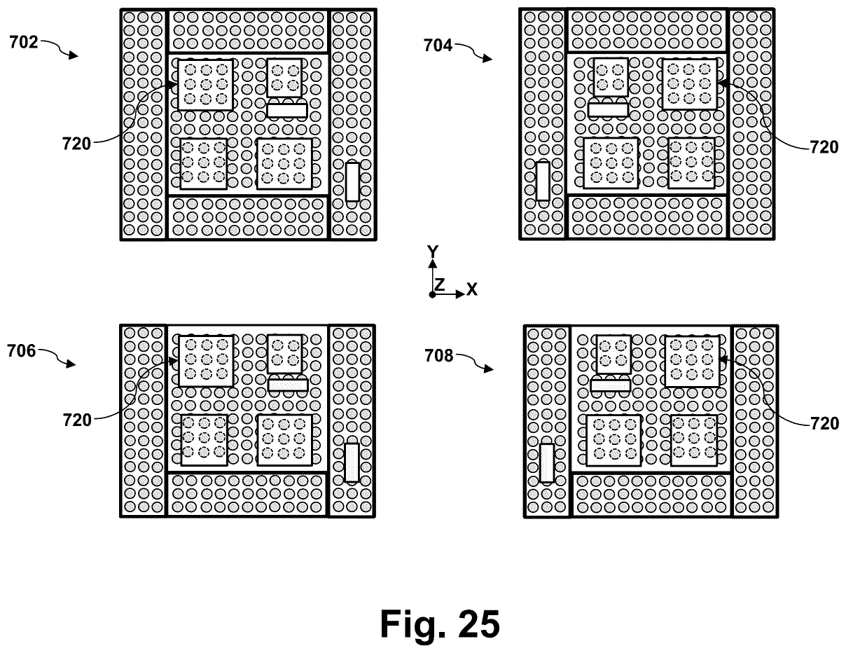

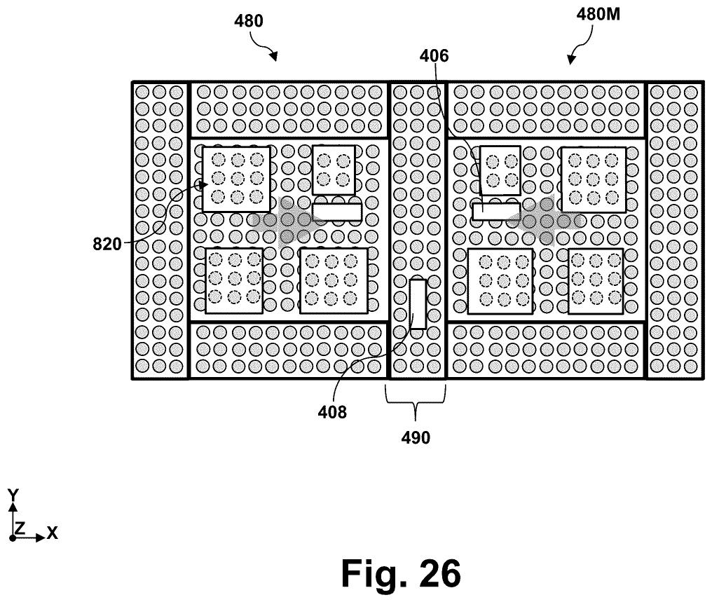

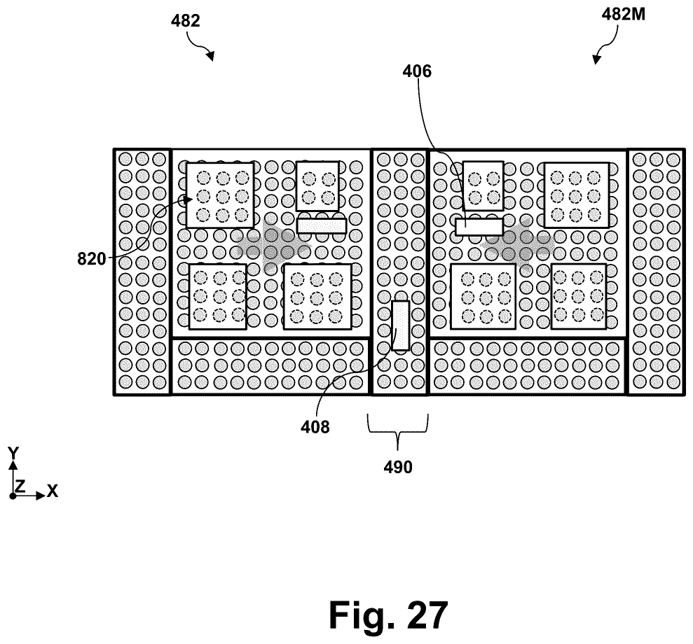

Referring to FIGS. 9 and 25, method 600 includes a block 612 where a photomask that includes the scribe line pad pattern is fabricated. Although not explicitly shown in the figures, the photomask may be a transmissive photomask that includes a transparent fused silica plate having absorbing features formed of chromium (Cr) or iron oxide. The fabrication of the photomask may include deposition of various layers and patterning of these various layers using electron-beam (e-beam) photolithography. In some embodiments, because the photomask is used for stepwise exposure, it may also be referred to as a reticle. With respect to the O-frame design layout 400, the photomasks fabricated at block 612 may include a first photomask 702 that includes the first scribe line pad pattern 480 and a second photomask 704 that includes a mirror image 480M (shown in FIG. 26) of the first scribe line pad pattern 480. With respect to the U-frame design layout 401, the photomasks fabricated at block 612 may include a third photomask 706 that includes the second scribe line pad pattern 482 and a fourth photomask 708 that includes a mirror image 482M (shown in FIG. 27) of the second scribe line pad pattern 482. As will be described below, the first photomask 702, the second photomask 704, the third photomask 706, and the fourth photomask 708 may be used in different combinations to perform stepwise exposure. As shown in FIG. 25, each of the first photomask 702, the second photomask 704, the third photomask 706, and the fourth photomask 708 also includes functional pad patterns 720 in the carved-out device region 702. The functional pad patterns 720 are generated separately from the first scribe line pad pattern 480 or the second scribe line pad pattern 482. In some embodiments, the functional pad patterns 720 may be inserted into the device regions 402 after the generation of the first scribe line pad pattern 480 or the second scribe line pad pattern 482.

Referring to FIGS. 9 and 26-28, method 600 includes a block 614 where a photoresist layer on a substrate is stepwise exposed with use of the photomask and a mirror image of the photomask. In some embodiments, the substrate may be a semiconductor substrate similar to the first substrate 102 or the second substrate 202 shown in FIG. 1. Combinations of the first photomask 702, the second photomask 704, the third photomask 706, and the fourth photomask 708 are used when the photoresist layer is exposed to a radiation source, such as an ultraviolet (UV) source or a deep UV (DUV) source. As shown in FIGS. 26, 27 and 28, the photoresist layer may be subject to stepwise exposure to transfer patterns of the first scribe line pad pattern 480, a mirror image 480M of the first scribe line pad pattern 480, the second scribe line pad pattern 482, or a mirror image 482M of the second scribe line pad pattern 482 on the photoresist. It is noted that the substrate may be a semiconductor wafer similar to the semiconductor wafer 500 shown in FIG. 6 and the photoresist layer is disposed over a top surface of the semiconductor wafer. The stepwise exposure may propagate or be repeated along two perpendicular directions (such as the X direction and the Y direction shown in FIG. 6) until images of the first scribe line pad pattern 480, the mirror image 480M, the second scribe line pad pattern 482, or the mirror image 482M are transferred to a rectangular area on the semiconductor wafer.

FIG. 26 illustrate an example where the stepwise exposure repeatedly transfers images of the first scribe line pad pattern 480 and the mirror image 480M of the first scribe line pad pattern 480 onto the photoresist layer. The stepwise exposure includes use of the first photomask 702 and the second photomask 704 shown in FIG. 25. As shown in FIG. 26, neighboring images of the first scribe line pad pattern 480 and the mirror image 480M of the first scribe line pad pattern 480 may share a double exposure portion 490. Because of the multiple alignments at block 608, the dummy pad shapes in the double exposure portion 490 are vertically aligned. No abnormal shapes like the abnormal exposure image 495 in FIG. 7 will be generated. The functional pad patterns 720 of the first photomask 702 and the second photomask 704 result in functional pad images 820.

FIG. 27 illustrate an example where the stepwise exposure repeatedly transfers images of the second scribe line pad pattern 482 and the mirror image 482M of the second scribe line pad pattern 482 onto the photoresist layer. The stepwise exposure includes use of the third photomask 706 and the fourth photomask 708 shown in FIG. 25. As shown in FIG. 27, neighboring images of the second scribe line pad pattern 482 and the mirror image 482M of the second scribe line pad pattern 482 may share a double exposure portion 490. Because of the multiple alignments at block 608, the dummy pad shapes in the double exposure portion 490 are vertically aligned. No abnormal shapes like the abnormal exposure image 495 in FIG. 7 will be generated. The functional pad patterns 720 of the third photomask 706 and the fourth photomask 708 result in functional pad images 820.

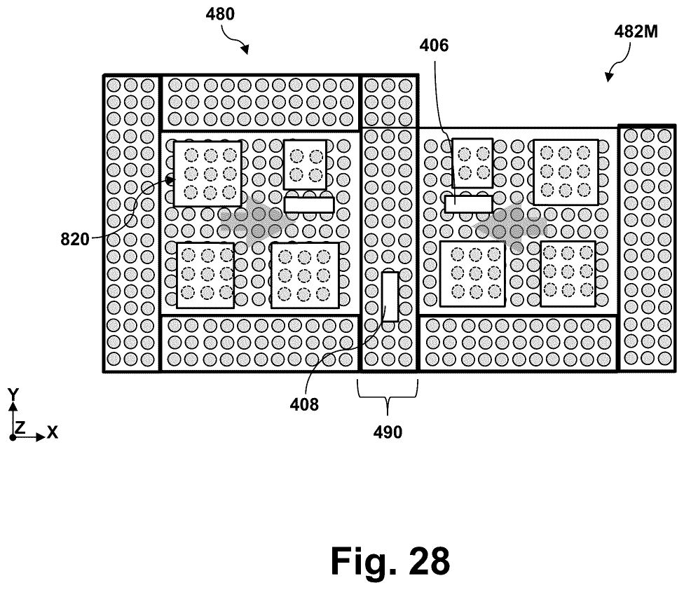

FIG. 28 illustrate an example where the stepwise exposure repeatedly transfers images of the first scribe line pad pattern 480 and the mirror image 482M of the second scribe line pad pattern 482 onto the photoresist layer. The stepwise exposure includes use of the first photomask 702 and the fourth photomask 708 shown in FIG. 25. As shown in FIG. 28, neighboring images of the first scribe line pad pattern 480 and the mirror image 482M of the second scribe line pad pattern 482 may share a double exposure portion 490. Because of the multiple alignments at block 608, the dummy pad shapes in the double exposure portion 490 are vertically aligned. No abnormal shapes like the abnormal exposure image 495 in FIG. 7 will be generated. The functional pad patterns 720 of the first photomask 702 and the fourth photomask 708 result in functional pad images 820.

FIGS. 26-28 illustrate double exposure portions 490 extending lengthwise along the Y direction. It should be understood that similar double exposure portions 490 may extend lengthwise along the X direction between the first scribe line pad pattern 480 and a mirror image 480M of the first scribe line pad pattern 480 below or between the first scribe line pad pattern 480 and the mirror image 482M of the second scribe line pad pattern 482 below.

Referring to FIG. 9, method 600 includes a block 616 where further processes are performed. Such further processes may include, for example, etching a dielectric layer under the patterned photoresist layer using the patterned photoresist layer as an etch mask. For example, the photoresist layer may be deposited on a hard mask layer, which is deposited on a dielectric layer similar to the first dielectric layer 122 and the second dielectric layer 222 shown in FIG. 1. In some implementations, the dielectric layer may include silicon oxide or silicon oxynitride. After stepwise exposure at block 614 transfers images of the first scribe line pad pattern 480, the mirror image 480M of the first scribe line pad pattern 480, the second scribe line pad pattern 482, or the mirror image 482M of the second scribe line pad pattern 482 on the photoresist layer. The patterned photoresist layer may be subjected to a post-exposure bake. Thereafter, the baked photoresist layer may be developed in a developer. After the photoresist layer is baked in a post-developing bake process, it is applied as an etch mask to pattern the underlying hard mask layer. The pattern hard mask layer is then applied as an etch mask to pattern the dielectric layer. In some embodiments, a metal layer may then be deposited over the dielectric layer. After a planarization process, a bonding layer similar to the first pad layer 120 or the second pad layer 220 shown in FIG. 1 may be formed.

When method 600, which is described above in conjunction with FIGS. 10-28 is applied to form the package structure 10 shown in FIG. 1, the package structure 10 would include several distinctive features. In one aspect, the plurality of first transistors 106 in the bottom die 100 and the plurality of second transistors 206 in the top die 200 may be of different technology nodes. That is, they may have substantially different gate pitches and gate lengths. For example, in a 28 nm technology node, a representative gate length may be between about 27 nm and about 32 nm and a representative gate pitch may be between about 110 nm and about 130 nm. In a 40 nm technology node, a representative gate length may be between about 35 nm and about 45 nm and a representative gate pitch may be between about 155 nm and about 170 nm. In a 65 nm technology node, a representative gate length may be between about 65 nm and about 75 nm and a representative gate pitch may be between about 250 nm and about 270 nm. In one embodiment, the bottom die 100 is an imaging signal processing (ISP) die where the plurality of first transistors 106 are of the 28 nm technology node. The top die 200 is a CMOS image sensor (CIS) die where the plurality of second transistors 206 are of the 65 nm technology node. In another aspects, dies of different technology nodes may have different scribe line arrangement. For example, dies of the 28 nm technology node may have the O-frame layout shown in FIG. 10 while dies of the 40 nm or 65 nm technology nodes may have the U-frame layout shown in FIG. 11. That is, in the foregoing embodiment where the bottom die 100 is an ISP die and the bottom die 200 is a CIS die, the bottom die 100 has the O-frame layout and the top die 200 has the U-frame layout. This once again demonstrates how important it is to center the dummy pattern 450 with respect to different rectangular areas of the scribe line region to ensure full alignment of the double exposure regions.

In one exemplary aspect, the present disclosure is directed to a three-dimensional integrated circuit (3DIC) device. The three-dimensional integrated circuit (3DIC) device includes a first device including a first layer that includes a first layout and a first scribe line region and a second device including a second layer that includes a second layout and a second scribe line region. The first layer is bonded to the second layer. The first layout is a mirror image of the second layout. The first scribe line region includes a first plurality of dummy features symmetrically arranged with respect to a center of the first scribe line region.

In some embodiments, the second scribe line region includes a second plurality of dummy features symmetrically arranged with respect to a center of the second scribe line region. In some embodiments, the first scribe line region includes a first overlay pattern, the second scribe line region includes a second overlay pattern.

In another exemplary aspect, the present disclosure is directed to a method. The method includes receiving a design layout that includes a device region disposed in a scribe line region, identifying a center portion of the scribe line region surrounding the device region and an edge portion surrounding the center portion, dividing the edge portion into a plurality of rectangular areas, super-positioning a dummy pattern on each of the plurality of rectangular areas to obtain edge dummy patterns, super-positioning the dummy pattern on the center portion to obtain center dummy patterns, carving out a portion of the dummy pattern corresponding to the device region from the center dummy patterns to obtain net center dummy patterns, generating a scribe line dummy pattern based on the edge dummy patterns and the net center dummy patterns, and fabricating a first photomask including the scribe line dummy pattern.

In some embodiments, the method further includes fabricating a second photomask including a mirror image of the scribe line dummy pattern. In some embodiments, the method may further include receiving a wafer including a photoresist layer, and stepwise transferring a first image of the first photomask and a second image of the second photomask onto the photoresist layer. In some embodiments, the stepwise transferring forms an array including a plurality of the first images and a plurality of the second images. In some implementations, the stepwise transferring is performed such that the first image overlaps with the second image at a double exposure region. In some embodiments, the first image includes first dummy features and the second image includes second dummy features and the first dummy features and the second dummy features in the double exposure region completely overlap. In some instances, the double exposure region includes a rectangular shape. In some embodiments, the edge portion surrounds the center portion on three sides and the plurality of rectangular areas includes three rectangular areas. In some embodiments, the edge portion surrounds the center portion on four sides and the plurality of rectangular areas includes four rectangular areas.

In yet another exemplary aspect, the present disclosure is directed to a method. The method includes receiving a design layout that includes a device region disposed in a scribe line region, dividing the scribe line region into a center portion and an edge portion around the center portion, dividing the edge portion into a first area, a second area, a third area, and a fourth area, receiving a dummy pattern, identifying a first centroid of the dummy pattern, a second centroid of the first area, a third centroid of the second area, a fourth centroid of the third area, a fifth centroid of the fourth area, and a sixth centroid of the center portion, overlaying the dummy pattern on the first area such that the second centroid overlaps the first centroid to obtain a first pattern, overlaying the dummy pattern on the second area such that the third centroid overlaps the first centroid to obtain a second pattern, overlaying the dummy pattern on the third area such that the fourth centroid overlaps the first centroid to obtain a third pattern, overlaying the dummy pattern on the fourth area such that the fifth centroid overlaps the first centroid to obtain a fourth pattern, overlaying the dummy pattern on the center portion such that the sixth centroid overlaps the first centroid to obtain a fifth pattern, removing a first portion of the dummy pattern corresponding to the device region from the fifth pattern to obtain a sixth pattern, and generating a dummy pad pattern design based on the first pattern, the second pattern, the third pattern, the fourth pattern, and the sixth pattern, and fabricating a first photomask including the dummy pad design.

In some embodiments, each of the first area, the second area, the third area, the fourth area, and the center portion is rectangular in shape. In some embodiments, the method further includes before the fabricating, inserting functional pad patterns into the dummy pad design. In some embodiments, the method further include fabricating a second photomask including an mirror image of the dummy pad design. In some implementations, the method further includes receiving a wafer including a photoresist layer, and stepwise transferring an image of the first photomask and an image of the second photomask onto the photoresist layer. In some implementations, the image of the first photomask at least partially overlap with the image of the second photomask in a double exposure portion. In some embodiments, the center portion further includes an overlay (OVL) pattern, a critical dimension bar (CDBAR) pattern, a process control monitor (PCM) pattern, an identification (IDNT) pattern, or a wafer acceptance test (WAT) pattern. In some embodiments, the removing includes removing a second portion of the dummy pattern that corresponds to the OVL pattern, the CDBAR pattern, the PCM pattern, the IDNT pattern, or the WAT pattern from the sixth pattern.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a design layout that includes a rectangular center region and an edge portion surrounding at least three sides of the rectangular center region, the rectangular center region comprising at least one device region;
providing a dummy pattern comprising dummy pad shapes;
dividing the edge portion into a plurality of rectangular areas;
identifying geometric centers of the rectangular center region, the dummy pattern, and the plurality of rectangular areas;
aligning a geometric center of dummy pattern to the respective geometric center of each of the rectangular center region and the plurality of rectangular areas to obtain overlapping areas of the dummy pattern with each of the rectangular center region and the plurality of rectangular areas;
combining the overlapping areas to form a combined pattern;
replacing the dummy pattern over the at least one device region with functional patterns to form a bonding pad pattern; and
fabricating a first photomask comprising the bonding pad pattern.

2. The method of claim 1, further comprising:
fabricating a second photomask comprising a mirror image of the bonding pad pattern.

3. The method of claim 2, further comprising:
providing a wafer comprising:
a dielectric layer,
a hard mask layer over the dielectric layer, and
a photoresist layer over the hard mask layer; and
stepwise transferring a first image of the first photomask and a second image of the second photomask onto the photoresist layer.

4. The method of claim 3, further comprising:
developing the photoresist layer to form a patterned photoresist layer;
etching the hard mask layer using the patterned photoresist layer as an etch mask to form a patterned hard mask;
etching the dielectric layer using the patterned hard mask as an etch mask to form openings;
depositing a metal layer over the openings; and
after the depositing, planarizing the metal layer and the dielectric layer to remove excess metal layer.

5. The method of claim 3, wherein the stepwise transferring is performed such that the first image and the second image overlaps at a double exposure region. in at least one of the plurality of rectangular areas.

6. The method of claim 5, wherein the double exposure region corresponds to at least one of the plurality of rectangular areas.

7. The method of claim 5, wherein, within the double exposure region, dummy pad shapes in the first image are aligned with dummy pad shapes in the second image.

8. The method of claim 1, wherein the rectangular center region further comprises a process control monitor (PCM) pattern.

9. The method of claim 8, further comprising:
after the combining, removing the dummy patterns over the PCM pattern from the combined pattern.

10. A method, comprising:
providing a design layout that includes a rectangular center region and an edge portion surrounding at least three sides of the rectangular center region, the rectangular center region comprising at least one device region and a process control monitor (PCM) pattern;
providing a dummy pattern comprising dummy pad shapes;
dividing the edge portion into a plurality of rectangular areas;
identifying geometric centers of the rectangular center region, the dummy pattern, and the plurality of rectangular areas;
aligning a geometric center of dummy pattern to the respective geometric center of each of the rectangular center region and the plurality of rectangular areas to obtain overlapping areas of the dummy pattern with each of the rectangular center region and the plurality of rectangular areas;
combining the overlapping areas to form a combined pattern;
after the combining, removing the dummy patterns over the PCM pattern from the combined pattern;
replacing the dummy pattern over the at least one device region with functional patterns to form a bonding pad pattern;
fabricating a first photomask comprising the bonding pad pattern; and
fabricating a second photomask comprising a mirror image of the bonding pad pattern.

11. The method of claim 10, further comprising:
providing a wafer comprising:
a dielectric layer,
a hard mask layer over the dielectric layer, and
a photoresist layer over the hard mask layer; and
stepwise transferring a first image of the first photomask and a second image of the second photomask onto the photoresist layer.

12. The method of claim 11, further comprising:
developing the photoresist layer to form a patterned photoresist layer;
etching the hard mask layer using the patterned photoresist layer as an etch mask to form a patterned hard mask;
etching the dielectric layer using the patterned hard mask as an etch mask to form openings;
depositing a metal layer over the openings; and
after the depositing, planarizing the metal layer and the dielectric layer to form functional pads over the at least one device region and dummy pads over regions other than the at least one device region and the PCM pattern.

13. The method of claim 12, wherein each of the dummy pads has a diameter between about 0.2 μm and about 2.5 μm.

14. The method of claim 12, wherein the metal layer comprises copper (Cu), tantalum (Ta), nickel (Ni), cobalt (Co), aluminum (Al), a combination thereof, or an alloy thereof.

15. The method of claim 11, wherein the stepwise transferring is performed such that the first image and the second image overlaps at a double exposure region. in at least one of the plurality of rectangular areas.

16. The method of claim 15, wherein the double exposure region corresponds to at least one of the plurality of rectangular areas.

17. A method, comprising:
providing a design layout that includes a rectangular center region and an edge portion surrounding at least three sides of the rectangular center region, the rectangular center region comprising at least one device region and a process control monitor (PCM) pattern;
providing a dummy pattern comprising dummy pad shapes;
dividing the edge portion into a plurality of rectangular areas;
identifying geometric centers of the rectangular center region, the dummy pattern, and the plurality of rectangular areas;
aligning a geometric center of dummy pattern to the respective geometric center of each of the rectangular center region and the plurality of rectangular areas to obtain overlapping areas of the dummy pattern with each of the rectangular center region and the plurality of rectangular areas;
combining the overlapping areas to form a combined pattern;
after the combining, removing the dummy patterns over the PCM pattern from the combined pattern;
replacing the dummy pattern over the at least one device region with functional patterns to form a bonding pad pattern;
fabricating a first photomask comprising the bonding pad pattern;
fabricating a second photomask comprising a mirror image of the bonding pad pattern;
providing a wafer comprising:
a dielectric layer,
a hard mask layer over the dielectric layer, and
a photoresist layer over the hard mask layer; and
stepwise transferring a first image of the first photomask and a second image of the second photomask onto the photoresist layer.

18. The method of claim 17, further comprising:
developing the photoresist layer to form a patterned photoresist layer;
etching the hard mask layer using the patterned photoresist layer as an etch mask to form a patterned hard mask;
etching the dielectric layer using the patterned hard mask as an etch mask to form openings;
depositing a metal layer over the openings; and
after the depositing, planarizing the metal layer and the dielectric layer to form functional pads over the at least one device region and dummy pads over regions other than the at least one device region and the PCM pattern.

19. The method of claim 18, wherein each of the dummy pads has a diameter between about 0.2 μm and about 2.5 μm.

20. The method of claim 17,
wherein the stepwise transferring is performed such that the first image and the second image overlaps at a double exposure region. in at least one of the plurality of rectangular areas,
wherein the double exposure region corresponds to at least one of the plurality of rectangular areas.
